(19) United States
(12) Patent Application Publication
(10) Pub. No.: US 2008/0048272 A1
(43) Pub. Date: Feb. 28, 2008

(54) SILICIDATION MONITORING PATTERN FOR USE IN SEMICONDUCTOR MANUFACTURING PROCESS

(76) Inventor: Ji-Ho Hong, Gyeonggi-do (KR)

Correspondence Address: SHERR & NOURSE, PLLC, 620 HERNDON PARKWAY, SUITE 200, HERNDON, VA, 20170, US

(21) Appl. No.: 11/841,035

(22) Filed: Aug. 20, 2007

(30) Foreign Application Priority Data
Aug. 22, 2006 (KR) 10-2006-0079319

(51) Int. Cl. H01L 29/78; H01L 21/336; H01L 21/66

(52) U.S. Cl. 257/401; 438/17; 438/197; 257/E29.255; 257/E21.409; 257/E21.531

(57) ABSTRACT

A silicidation monitoring pattern may electrically measure resistance of a polygate line after silicidation to measure open and/or short-circuiting of the polygate line. A silicidation monitoring pattern may minimize production costs. A silicidation monitoring pattern may quickly provide feedback based on a fabrication status.

This application claims the benefit under 35 U.S.C. 119 Korean Patent Application No. 10-2006-0079319, filed on Aug. 22, 2006, which is hereby incorporated by reference in its entirety.

### BACKGROUND

Methods for forming cobalt silicide and/or nickel silicides in semiconductor manufacturing processes may reduce contact resistance at gate areas, a source/drain areas, and contacts formed in a source/drain area. Transmission electron microscopy (TEM) analysis data and electric data of detected contact resistance may be monitored to determine whether a silicidation process in a silicide area is normal.

A TEM analysis method may be a destructive monitoring method, in which losses of a wafer may occur. A TEM analysis method may take a relatively long time to perform and may be limited to monitoring of a local area. A method of electrically measuring contact resistance may monitor an overall area of a wafer instead of monitoring only a local area of the wafer, which may result in relatively reliable data. However, a monitoring method based on measurement of electric contact resistance may only monitor a specific area including contacts and may not be able to determine the presence or absence of abnormal contact resistance caused by tolerance from an implantation process for forming a source/drain area. Accordingly, a method of monitoring based on measurement of electric contact resistance may be inadequate to monitor a normal silicidation forming process.

In order to determine whether a silicidation for a polygate is formed, a method of monitoring based on measurement of electric contact resistance must measure contact resistance for metal wiring layers most recently formed. Accordingly, a method of monitoring based on measurement of electric contact resistance must perform a variety of processes from polygate patterning to a metal wiring layer process, which may make it difficult to quickly perform a feedback process. With lack of feedback, a method of monitoring based on measurement of electric contact resistance may not identify defective semiconductor devices quickly, resulting in unnecessary waste of production costs. These disadvantages may be compounded in 90 nm semiconductor processing technology.

### SUMMARY

Embodiments relate to a silicidation monitoring pattern used in a semiconductor manufacturing process. In embodiments, a silicidation monitoring pattern may monitor the presence and/or absence of a defective silicide process that reduces contact resistance and/or gate-electrode resistance. In embodiments, a test pattern structure may directly measure and determine if a polygate line and/or a spacer pattern are closed or open, determine if an impurity implantation process for forming a source/drain area was adequately performed, and/or monitor a normal silicidation forming process.

Embodiments relate to a silicidation monitoring pattern for measuring open and/or short-circuiting of a polygate line. Embodiments relate to a silicidation monitoring pattern for measuring resistance of a polygate line after silicidation to measure open and/or short-circuiting of the polygate line. Embodiments relate to a silicidation monitoring pattern which may minimize production costs. Embodiments relate to a silicidation monitoring pattern which may quickly provide feedback based on a fabrication status.

Embodiments relate to a silicidation monitoring pattern including at least one of: A plurality of polypads formed on and/or over a semiconductor substrate. A plurality of N-well and P-well areas periodically arranged between the polypads to occupy a predetermined area. An active area formed on and/or over each of the N-well area and the P-well area. A polygate line continuously formed on and/or over the N-well area, the P-well area, and the active area at predetermined intervals that are configured in a connected pattern, is silicidation-processed, and/or is connected to the polypads.

In embodiments, a pattern of a polygate line may be configured in the form of a snake. In embodiments, there may be two polypads, such that the silicidation monitoring pattern is a bar-type silicidation monitoring pattern. In embodiments, there may be four polypads, such that the silicidation monitoring pattern is a Van der pauw-type silicidation monitoring pattern. Embodiments may measure resistance using several polypads, and determines whether the polygate line is closed or open based on a measured resistance value.

### DRAWINGS

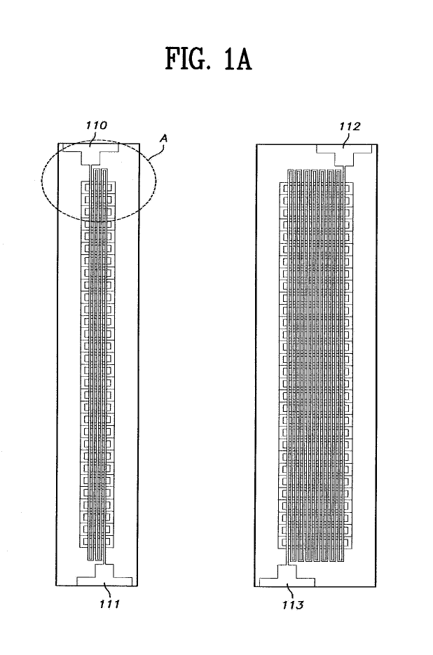

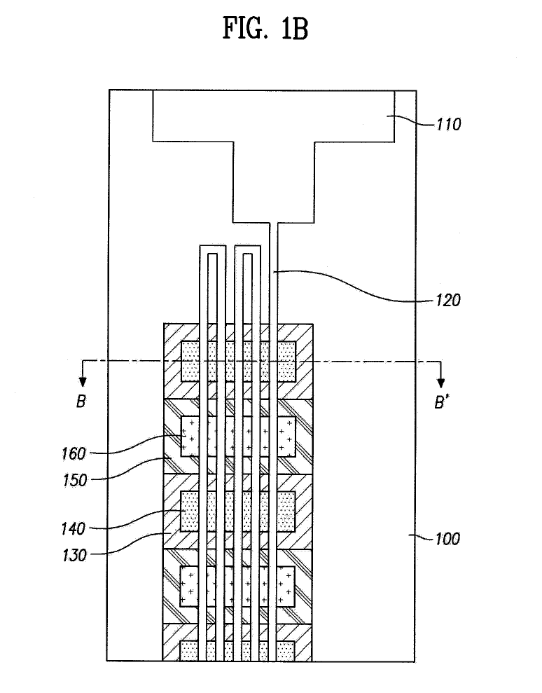

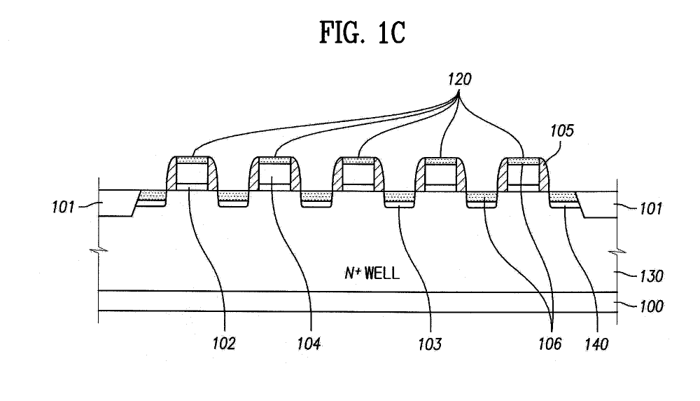

Example FIGS. 1A, 1B, and 1C illustrate bar-type silicidation monitoring patterns, in accordance with embodiments.

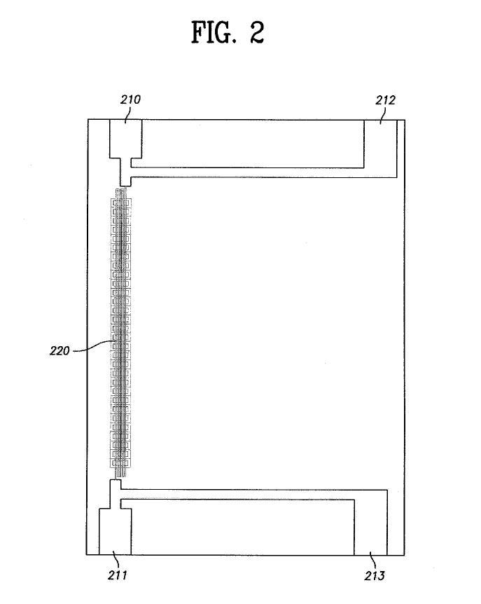

Example FIG. 2 illustrates a Van der pauw-type silicidation monitoring pattern according to embodiments.

### DESCRIPTION

Instead of indirectly monitorng a silicidation process by electrically measuring contact resistance, embodiments use a silicidation monitoring pattern which may directly measures resistances of several polypads. Embodiments may detect open-circuits and/or short-circuits in a polygate line and a space pattern. Embodiments may detect abnormal source/drain implantation formations. Embodiments may monitor a silicidation process.

Example FIG. 1A illustrates a bar-type silicidation monitoring pattern, according to embodiments. Example FIG. 1B is an enlarged view of area A in FIG. 1A, in accordance with embodiments. Example FIG. 1C is a cross-sectional view along line B-B′ in FIG. 1B, in accordance with embodiments.

As illustrated in FIGS. 1A through 1C, a bar-type silicidation monitoring pattern includes polygate lines 120 arranged between polypad 110 and polypad 111 after completing a poly-silicidation process, in accordance with embodiments. In embodiments, polygate lines 120 are continuously arranged in a snake pattern having intervals at a predetermined distance. Embodiments measure the resistance of polypad 110 and polypad 111 connected to the bar-type silicidation monitoring pattern using a probe to determine if polygate lines 120 are closed or open.

As illustrated on the right side of example FIG. 1A, the length of polygate line 120 may be longer (between polypad 112 and polypad 113) compared to the length of polygate line 120 on the left side of example FIG. 1A (between polypad 110 and polypad 111), in accordance with embodiments. Polygate line 120 between polypad 112 and polypad 113 may be continuously arranged in the shape of a snake at intervals having a predetermined distance to form a bar-type silicidation monitoring pattern. In embodiments, resistance of polypad 112 and polypad 113 may be electrically measured, using a probe, to determine if polygate line 120 is closed or open. One of ordinary skill in the art would appreciate different lengths of polygate lines, in accordance with embodiments.

Example FIG. 1B illustrates an enlarged view of area A of FIG. 1A. As illustrated in example FIG. 1A, N-well area 130 and P-well area 150 in semiconductor substrate 100 may be formed between the polypad 110 and polypad 111, in accordance with embodiments. In embodiments, active areas 140 and 160 may be arranged on N-well area 130 and/or the P-well area 150 (e.g. in the form of an island). Polygate line 120 may be continuously formed on and/or over active areas 140 and 160 at intervals of a predetermined distance (e.g. in a snake pattern) and may connect polypad 110 and polypad 111.

In embodiments, Polygate line 120 may be configured in the form of a snake in accordance with a minimum line and a threshold value of a spacer. Active areas 140 and 160 under the polygate line 120 may be formed according to a minimum extension rule allowed by the design rules in association with the active areas and the space between the well and the source/drain implantation patterns, in accordance with embodiments.

In embodiments, a pattern between N-well area 130 and P-well area 150 and the pattern between a source/drain area of N-well area 130 and a source/drain area of the P-well area 150 may be brought into contact with each other without overlapping each other on a shallow trench isolation (STI) layer. If an implantation process exceeds a predetermined tolerance for forming a source/drain area and/or a silicidation process is formed abnormally (e.g. excessive doses contained in the overlapped area), monitoring of resistance measured by polypad 110 and polypad 111 may determine the presence or absence of an abnormal silicidation process, in accordance with embodiments.

Example FIG. 1C illustrates a method of forming a bar-type silicidation monitoring pattern, in accordance with embodiments. An initial oxide layer and/or a nitride layer may be deposited on and/or over semiconductor substrate 100. A photoresist layer may be deposited on and/or over semiconductor substrate 100. The photoresist layer may be exposed to light in a predetermined pattern through a mask to pattern exposed the nitride layer and/or the oxide layer. The nitride layer and/or the oxide layer may be selectively etched and removed based on the predetermined pattern. Exposed semiconductor substrate 100 may be etched to a predetermined depth and trench 101 (e.g. a shallow trench isolation (STI) layer) may be formed. The photoresist layer may then be removed. An insulating layer may be deposited (e.g. to have a relatively large thickness) on and/or over semiconductor substrate 100 including trench 101, such that trench 101 is filled with the insulation layer.

In embodiments, a photoresist layer may be deposited on and/over semiconductor substrate 100 including the insulation layer. A photosensitive layer may be selectively exposed to light, such that a photoresist pattern remains on and/or over the insulation layer formed on and/or over trench 101. The insulation layer may be etched using the photoresist pattern as a mask to form a trench insulation layer pattern. In embodiments, after removing the photoresist layer, the trench insulation layer pattern may be planarized (e.g. using chemical mechanical polishing (CMP)) to remove the nitride layer and the oxide layer.

In embodiments, semiconductor substrate 100 may be cleaned (e.g. cleaned with deionized (DI) water) and dried. P-type dopant or N-type dopant may be ion-implanted and/or diffused in the dried area, such that N-well area 130 and P-well area 150 have a relatively high-density uniformity on and/or over semiconductor substrate 100. An oxide layer may be formed on and/or over semiconductor substrate 100 (e.g. including the N-well area 130 and P-well area 150). Gate oxide layer 102 may be formed on and/or over corresponding areas of N-well area 130 and P-well area 150 by photolithography using a gate mask.

In embodiments, a pattern may be formed on corresponding parts of N-well area 130 and/or P-well area 150 between the trench 101 and the gate oxide layer 102 using gate oxide layer 102 as a mask by ion-implanting different dopant materials having opposite conductivities as the corresponding N-well area 130 and P-well area 150. For example, a specific material (P or As) may be ion-implanted as a N-type dopant in N-well area 130, in accordance with embodiments. For example, specific material (B) may be ion-implanted as a P-type dopant in P-well area 150, in accordance with embodiments. In embodiments, an N+-type diffusion layer and a P+-type diffusion layer 103 may be implemented in source/drain areas. An N+-polysilicon layer may be formed on and/or over a gate oxide layer arranged on and/or over P-well area 150, according to embodiments. A P+-polysilicon layer 104 is formed on and/or over the gate oxide layer 102 arranged on the N-well area 130, according to embodiments. In order to isolate N+-type polysilicon and/or P+-type polysilicon layer 104 formed on and/or over gate oxide layer 102 from N+-type diffusion layer and the P+-type diffusion layer 103, an insulation layer may be deposited using Low Pressure Chemical Vapour Deposition (LPCVD), in accordance with embodiments. Spacer oxide layer 105 may be formed (e.g. by anisotropic etching) on a sidewall of the gate oxide layer 102 on which N+-polysilicon and/or P+-polysilicon layer 104 is deposited, in accordance with embodiments.

In embodiments, if a N+-type diffusion layer or P+-type diffusion layer 103 form a source/drain area and a N+-polysilicon layer or P+-polysilicon layer 104 form a gate area, opposite dopant types of materials may be ion implanted (e.g. by ion-implanted with low energy). For example, BF2 and/or B may be used P-type dopant, in accordance with embodiments.

In embodiments, after an N+-type semiconductor area is formed to have P+-type semiconductor characteristics through ion implantation of P-type dopant materials, a specific material (e.g., titanium) may be uniformly deposited on and/or over semiconductor substrate 100 (e.g. by AtmosPheric Chemical Vapor Deposition (APCVD)) to perform silicidation. In embodiments, silicidation may minimize the contact resistance (e.g. caused by interconnecting electrodes of semiconductor elements and/or caused by interconnections between semiconductor elements) and the resistance of a polygate electrode. In embodiments, semiconductor substrate 100 may include trench 101, a N+-type diffusion layer, P+-polysilicon layer 103, a N+-polysilicon layer, and P+-type polysilicon layer 104.

In embodiments, a low-temperature Rapid Thermal Annealing RTA process may be performed to allow deposited titanium to react with silicon, such that titanium silicide layer 106 may be formed on and/or over a N+-type diffusion layer, P+-type diffusion layer 103, a N+-polysilicon layer, and/or P+-polysilicon layer 104.

Titanium silicide layer 106 may be selectively etched (e.g. etched by NH40H, H2O2, and H2O), such that silicide layer 106 only remains on a N+-type diffusion layer, P+-type diffusion layer 103, a N+-polysilicon layer, and/or P+-type polysilicon layer 104, in accordance with embodiments. Example FIGS. 1B and 1C illustrated that polygate line 120 may be formed with five successive patterns (spaced apart from each other at predetermined distance intervals), in accordance with embodiments. As illustrated in example FIG. 1B, upon completion of a silicidation process, the five patterns may have a snake pattern (e.g. configured in the shape and/or form of a snake) and are connected to polypad 110 and polypad 111, in accordance with embodiments.

In embodiments, in order to monitor a silicidation process of a pattern of polygate lines (e.g. five polygate lines 120 illustrated in example FIGS. 1B and 1C), resistance is directly measures by applying a probe to polypads (e.g. polypad 110 and polypad 111 connected to polygate line 120) to determines if open- or short-circuiting occurs between the polygate line and the space pattern. In embodiments, in order to monitor whether a source/drain implantation process was properly implemented, resistance is directly measures by applying a probe to polypads (e.g. polypad 110 and polypad 111 connected to polygate line 120).

Example FIG. 2 illustrates a Van der pauw-type silicidation monitoring pattern, according to embodiments. As illustrated in example FIG. 2, a Van der pauw-type silicidation monitoring pattern measures a resistance value of polygate line 220 using four terminals (e.g. polypad 210, polypad 211, polypad 212, and polypad 213), to determine if silicidation was properly formed. In embodiments, a Van der pauw - type silicidation monitoring pattern may be extended (similar to that illustrated in the right side of example FIG. 1A). In embodiments, a Van der pauw-type silicidation monitoring pattern may measure open- and/or short-circuiting of a polygate (e.g. polygate line 220).

Since embodiments electrically measure the contact resistance to a silicidation process, monitoring may be performed in a non-intrusive manner. For example, embodiments may electrically measure polypads by measuring the resistance of a polygate line (e.g. polygate line 220 and polygate line 120) to determine if the polygate line is closed or open. In accordance with embodiments, waste of raw materials used in a semiconductor process may be prevented, minimization of production costs, and relatively quick feedback during fabrication processes may be realized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first polypad formed at least one of on a semiconductor substrate and over the semiconductor substrate;
a second polypad formed at least one of on the semiconductor substrate and over the semiconductor substrate; and
a polygate line formed at least one of on the semiconductor substrate and over the semiconductor substrate, wherein:
the polygate line connects the first polypad and the second polypad,
a plurality of transistors are formed along the polygate line, and
the length of the polygate line is greater than the distance between the first polypad and the second polypad by approximately a multiple of the distance between the first polypad and the second polypad.

2. The apparatus of claim 1, wherein the apparatus is a silicidation monitoring pattern.

3. The apparatus of claim 2, wherein the silicidation monitoring pattern is a bar-type silicidation monitoring pattern

4. The apparatus of claim 1, wherein:
a plurality of N-well areas and a plurality of P-well areas formed between the first polypad and the second polypad in the semiconductor substrate;
said plurality of N-well areas and said plurality of P-well areas comprises active areas; and
the polygate line is formed over the active areas.

5. The apparatus of claim 1, wherein the polygate line has a shape of a snake between the first polygate and the second polygate.

6. The apparatus of claim 1, comprising a third polypad and a fourth polypad, wherein:
the third polypad is connected to the first polypad; and
the fourth polypad is connected to the second polypad.

7. The apparatus of claim 6, wherein the apparatus is a Van der pauw -type silicidation monitoring pattern.

8. The apparatus of claim 1, wherein a silicidation process is monitored by measuring a resistance between the first polypad and the second polypad.

9. The apparatus of claim 1, wherein an ion implantation process is monitored by measuring a resistance between the first polypad and the second polypad.

10. The apparatus of claim 1, wherein formation of semiconductor elements is monitored by determining if a connection between the first polypad and the second polypad is at least one of a short circuit and an open circuit.

11. A method comprising:
forming a first polypad at least one of on a semiconductor substrate and over the semiconductor substrate;
forming a second polypad at least one of on the semiconductor substrate and over the semiconductor substrate; and
forming a polygate line at least one of on the semiconductor substrate and over the semiconductor substrate, wherein:
the polygate line connects the first polypad and the second polypad,
a plurality of transistors are formed along the polygate line, and
the length of the polygate line is greater than the distance between the first polypad and the second polypad by approximately a multiple of the distance between the first polypad and the second polypad.

12. The method of claim 11, wherein the method forms a silicidation monitoring pattern.

13. The method of claim 12, wherein the silicidation monitoring pattern is a bar-type silicidation monitoring pattern

14. The method of claim 11, comprising:
forming a plurality of N-well areas and a plurality of P-well areas between the first polypad and the second polypad in the semiconductor substrate;
forming active areas in said plurality of N-well areas and said plurality of P-well areas; and
forming the polygate line over the active areas.

15. The method of claim 11, wherein the polygate line has a shape of a snake between the first polygate and the second polygate.

16. The method of claim 11, comprising forming a third polypad and a fourth polypad, wherein:
the third polypad is connected to the first polypad; and
the fourth polypad is connected to the second polypad.

17. The method of claim 16, wherein the method forms a Van der pauw-type silicidation monitoring pattern.

18. The method of claim 11, wherein a silicidation process is monitored by measuring a resistance between the first polypad and the second polypad.

19. The method of claim 11, wherein an ion implantation process is monitored by measuring a resistance between the first polypad and the second polypad.

20. The method of claim 11, wherein formation of semiconductor elements is monitored by determining if a connection between the first polypad and the second polypad is at least one of a short circuit and an open circuit.
